(19) United States
(12) Patent Application Publication
(10) Pub. No.: US 2010/0216299 A1
(43) Pub. Date: Aug. 26, 2010

(54) SUBSTRATE PREPARATION FOR ENHANCED THIN FILM FABRICATION FROM GROUP IV SEMICONDUCTOR NANOPARTICLES

(76) Inventors: Dmitry Poplavskyy, San Jose, CA (US); Mason Terry, Belmont, CA (US)

Correspondence Address: Foley & Lardner LLP, Suite 500, 3000 K STREET NW, Washington, DC, 20007, US

(21) Appl. No.: 12/450,938

(22) PCT Filed: Feb. 29, 2008
(86) PCT No.: PCT/IB2008/000463

§ 371 Date: May 6, 2010

Related U.S. Application Data
(60) Provisional application No. 60/902,184, filed on Feb. 20, 2007.

(51) Int. Cl. H01L 21/208

(52) U.S. Cl. 438/502; 977/777; 257/E21.115

(57) ABSTRACT

A method for producing a thin film promoter layer is disclosed. The method includes depositing a Group IV semiconductor ink on a substrate, the Group IV semiconductor ink including a set of Group IV semiconductor nanoparticles and a set of metal nanoparticles to form a porous compact. The method also includes heating the substrate to a first temperature between about 350° C. to about 765° C. and for a first time period between 5 min to about 3 hours.

### FIELD OF DISCLOSURE

This disclosure relates to the preparation of substrates for the enhancement of thin film fabrication using Group IV semiconductor nanoparticles.

### BACKGROUND

The Group IV semiconductor materials enjoy wide acceptance as the materials of choice in a range devices in numerous markets such as communications, computation, and energy. Given the increasing demand for silicon, coupled with advanced thinking in the area of design for many semiconductor devices, thin film technologies are drawing significant interest. Currently, particular interest is aimed in the art at improvements in semiconductor thin film technologies due to the widely recognized disadvantages of the current chemical vapor deposition (CVD) technologies.

More specifically, a typical approach for creating thin film technologies based on crystalline silicon (c-Si) using CVD technologies is to deposit a layer of amorphous silicon (a-Si), followed by a crystallization step to form polycrystalline silicon (poly-Si). One major disadvantage of such is that the annealing step which promotes crystallization of the a-Si to poly-Si requires at temperature of at least 600° C.; generally for a prolonged period of time. This requirement impacts the cost of manufacturing due to the energy requirement, and limiting the ready use of low cost substrates. Still another aspect of improvement relates to methods for enhancing the grain size of poly-Si films formed using CVD processes. This has created a need in the art for alternatives to such fabrication processes.

One example of an alternative approach is in the area of selective solid phase crystallization (SSPC) where a selected chemical moiety is used to create nucleation sites in a Group IV semiconductor material, and enhance the crystallization process with a significantly reduced energy requirement. This decrease in energy requirement in turn is coupled with the ready use of a wider range of substrates, such as glass, stainless steel, and plastics.

Such an approach is described in Branz, et al. (US 20060208257; publication date, Sep. 21, 2006). In Branz, the deposition of a foreign template material on a substrate, such as glass, ceramics, metals and plastics is described. The foreign template material may be an oxide, such as cerium dioxide of zirconium dioxide, a silicide, such as nickel or cobalt, or a semiconductor, such as gallium nitride or gallium arsenide. The criteria for selecting the foreign template material is that it must be closely lattice matched to that of silicon. Using this approach, amorphous silicon can be deposited on the foreign template material using CVD technologies, and crystallized in polycrystalline silicon at temperatures of less than about 800° C.; moreover less than 600° C.

In another approach to SSPC, Richardson, et al. (US 20060108688; publication date May 25, 2006) use an approach to metal induced crystallization (MIC), in which nucleation sites are formed in a CVD-deposited amorphous silicon layer, which may be processed at a temperature below 600° C. to produce a large grain polysilicon laterally-grown template layer, and is therefore referred to as metal induced lateral crystallization (MILC). The nucleation sites for the MILC template layer are produced by numerous metal species, e.g. nickel, iron, cobalt, ruthenium, rhodium, palladium, osmium, iridium, platinum, copper, gold, indium, germanium, and aluminum, which can be deposited using numerous deposition techniques. In one embodiment, a suspension of nickel nanoparticles is used as a seed layer, and dispersed on an amorphous silicon layer. One advantage of using an MILC layer as a template layer is such a SSPC process is that the metal-containing silicide migrates laterally as the forming polycrystalline silicon layer is propagated. The large grain polysilicon layers formed from the MILC template layer may be fabricated using hot wire CVD (HWCVD) at between about 300° C. to about 500° C.

The issue of undesirable levels of metals remaining in Group IV semiconductor thin films using MIC approaches is addressed in Jang, et al. (US 20060270198; publication date Nov. 30, 2006). After deposition of an amorphous silicon layer on a substrate, a low level of a metal, such as nickel, is deposited on the amorphous silicon layer. The deposition of the metal is done to limit the amount of the metal in the amorphous silicon layer to between about 10¹⁷ atoms/cm³ to about 10¹⁹ atoms/cm³. In a process referred to as Field Effect MIC (FE-MIC), by using electric field to enhance the crystallization, the annealing temperature was lowered to between 400° C. to 500° C.

It is further known in the art that polycrystalline grain growth can be significantly assisted by the presence of high concentrations of dopants, in particular phosphorus and arsenic. Dopant concentrations at which the effect becomes noticeable in the CVD-deposited silicon are 3×10²⁰ cm⁻³ and 1×10¹⁹ cm⁻³, respectively. For example, in Turner et al. (U.S. Pat. No. 6,048,781; issue date Apr. 11, 2000), description is given of an improved method for recrystallization of silicon films to produce polycrystalline thin films having increased the grain size. The process can be used for the recrystallization of polycrystalline silicon thin films, as well as the crystallization of an amorphous silicon thin film. Accordingly, the process steps include depositing a first layer of arsenic on top of a semiconductor wafer substrate, followed by depositing a second layer of silicon; either polycrystalline or amorphous in nature, over the arsenic layer followed by a first annealing step of at least about 600° C. for a sufficient time to enhance the grain growth of the deposited silicon layer to form a polysilicon layer having sufficiently large grain size. Finally, in a last process step, a second annealing step is done at a higher temperature than the first annealing temperature in order to outgas arsenic from the polysilicon layer.

In that regard, other approaches include a combination of MIC techniques and the use of dopants. For example, Jang et al. (U.S. Pat. No. 6,835,608; Dec. 28, 2004) describe the use of phosphorous doping in conjunction with FE-MIC. The method for crystallizing an amorphous film includes forming an amorphous film containing an impurity on a substrate, forming a metal layer on the amorphous film, heat treating the amorphous film, and applying an electric field to the amorphous film. The phosphorous dopant is thought to reduce the concentration of crystallized nuclei formed during the initial phases of crystallization; which allows the formation of larger grains, enhancing the crystallinity thereby. In Joo et al. (US 20020139979; Oct. 3, 20020), boron doping, in conjunction MIC and MILC techniques, is used to increase the crystallization rate at temperatures between about 300° C. to about 500° C. in order to decrease the crystallization time.

All of the above described approaches to Group IV semiconductor thin film formation relate to the use of various template and dopants materials, or combinations thereof, to enhance the formation and quality of a bulk polycrystalline amorphous thin film layer formed from a bulk silicon thin film layer. However, the behavior of bulk materials cannot be used to predict the behavior of nanoparticle materials. For example, Goldstein (U.S. Pat. No. 5,576,248 with issue date of Nov. 19, 1996) discloses that the melting temperature depression of silicon nanoparticles is appreciable versus the melting of bulk. Further, the melting of nanoparticles approaches that of the bulk for nanoparticles of about 20 nm diameter. This is clearly a substantially different behavior than that of bulk Group IV semiconductor materials. Moreover, Goldstein discloses that for layers more than three to four particles deep, “ . . . vastly thicker layers, such as 20 to 30 particles deep begins to act as bulk materials and do not properly fuse at the low temperatures employed.”

With the emergence of nanotechnology, there is growing interest in leveraging the advantages of these new materials in order to produce low-cost devices with designed functionality using high volume manufacturing on nontraditional substrates. It is therefore desirable to leverage the knowledge of Group IV semiconductor materials and at the same time exploit the advantages of Group IV semiconductor nanoparticles for producing novel thin films that may be readily integrated into a number of electronic and optoelectric devices. The use of Group IV semiconductor nanoparticle materials to produce Group IV semiconductor thin films using substrates prepared to promote the transition from nanoparticle structure to densified thin film addresses a need in the art for fabricating large area thin films in high volume at low cost.

### SUMMARY

The invention relates, in one embodiment, to a method for producing a thin film promoter layer. The method includes depositing a Group IV semiconductor ink on a substrate, the Group IV semiconductor ink including a set of Group IV semiconductor nanoparticles and a set of metal nanoparticles to form a porous compact. The method also includes heating the substrate to a first temperature between about 350° C. to about 765° C. and for a first time period between 5 min to about 3 hours.

The invention relates, in another embodiment, to a method for producing a thin film promoter layer. The method includes depositing a Group IV semiconductor ink on a substrate, the substrate having an electrode layer disposed thereon, the group iv semiconductor ink including a set of Group IV semiconductor nanoparticles form a porous compact. The method also includes heating the substrate to a first temperature between about 350° C. to about 580° C. and for a first time period between 5 min to about 3 hours.

### BRIEF DESCRIPTION OF THE DRAWINGS

FIGS. 1A-1E are representations of the formation of a sintered Group N semiconductor thin film (FIG. 1D) and a polycrystalline thin film (FIG. 1E) fabricated from a porous compact (FIG. 1C) that was deposited on a promoter layer (FIG. 1B) that was prepared using an optional metal layer (FIG. 1A).

FIGS. 2A and 2B show the scanning electron micrograph (SEM) images of a sintered silicon thin film fabricated on a titanium silicide layer (FIG. 2A) and a sintered silicon thin film fabricated on molybdenum layer (FIG. 2B).

FIGS. 3A-3D are representations of the formation of a sintered Group IV semiconductor thin film (FIG. 3C) and a polycrystalline thin film (FIG. 3D) fabricated from a porous compact (FIG. 3B) deposited on a doped promoter layer (FIG. 3A).

FIGS. 4A and 4B show the scanning electron micrograph (SEM) images of a sintered silicon thin film fabricated on a n⁺ doped polysilicon layer (FIG. 4A) and a polysilicon thin film fabricated on a n⁺ doped polysilicon layer (FIG. 4B).

FIGS. 5A and 5B show the scanning electron micrograph (SEM) images of a sintered silicon thin film fabricated on a p⁺ doped polysilicon layer (FIG. 5A) and a polysilicon thin film fabricated on a p⁺ doped polysilicon layer (FIG. 5B).

### DETAILED DESCRIPTION

The use of Group IV semiconductor nanoparticle materials to produce Group IV semiconductor thin films using substrates prepared to form a promoter layer is described herein. Embodiments of promoter layers enhance the transition from Group IV semiconductor porous compact thin films having discrete nanoparticle structure to densified Group N semiconductor thin films; promoting thin film formation and quality thereby.

In some embodiments, a promoter layer is formed by using dispersions or inks of Group N semiconductor nanoparticles that are deposited on a metal layer that has been formed on a substrate such as glass, stainless steel, and plastics. In other embodiments, inks are formulated using mixtures of Group N semiconductor nanoparticles and metal nanoparticles that are deposited on a substrate and processed to form a promoter layer. In still other embodiments, after the deposition of a porous compact deposited on a substrate using a Group IV semiconductor nanoparticle ink, metal ions may be implanted into the porous compact using a variety of methods, and then processed to form a promoter layer. In all such embodiments, the embodiment of Group N porous compact and metal is processed at a temperature sufficient to form a metal silicide promoter layer. The metal silicide promoter layer may act to enhance the fabrication of a Group IV semiconductor thin film at a significantly lower process temperature versus the process temperature of forming a Group N semiconductor thin film from a bulk Group IV semiconductor material.

Additional embodiments of promoter layers disclosed herein are formed using inks of doped Group N semiconductor nanoparticles used to promote grain growth in order to fabricate Group N semiconductor thin films with enhanced grain size at a significantly lower process temperature versus the process temperature of forming a Group IV semiconductor thin film from a bulk Group IV semiconductor material. In still other embodiments, Group IV semiconductor nanoparticle inks are formulated so that metal and dopant species are deposited in a Group IV semiconductor porous compact thin film, producing promoter layers used to fabricate Group IV semiconductor thin films with enhanced grain sizes at a significantly lower process temperature versus the process temperature of forming a Group IV semiconductor thin film from a bulk Group IV semiconductor material.

The embodiments of the disclosed photoconductive thin film devices fabricated from Group IV semiconductor nanoparticle starting materials evolved from the inventors' observations that by keeping embodiments of the native Group IV semiconductor nanoparticles in an inert environment from the moment they are formed through the formation of Group IV semiconductor thin films, that such thin films so produced have properties characteristic of native bulk semiconductor materials. In that regard, the photoconductive devices that are then fabricated from such thin films are formed from materials for which the electrical, spectral absorbance and photoconductive properties are well characterized. This is in contrast, for example, thin films formed from the use of organic modifiers used to stabilize the reactive particles. In some examples where organic modifies are used, the Group IV nanoparticle materials are additionally significantly oxidized. The use of these types of nanoparticle materials produces hybrid thin films, which hybrid thin films do not have as yet the same desirable properties as traditional Group IV semiconductor materials.

As used herein, the term “Group IV semiconductor nanoparticle” generally refers to Group IV semiconductor nanoparticles having an average diameter between about 1.0 nm to 100.0 nm, and composed of silicon, germanium, and alpha-tin, or combinations thereof. In some embodiments, the Group IV semiconductor nanoparticles are hydrogen terminated. In other embodiments, the Group IV semiconductor nanoparticles are doped. With respect to shape, embodiments of Group IV semiconductor nanoparticles include elongated particle shapes, such as nanowires, or irregular shapes, in addition to more regular shapes, such as spherical, hexagonal, and cubic nanoparticles, and mixtures thereof. Additionally, the nanoparticles may be single-crystalline, polycrystalline, or amorphous in nature. As such, a variety of types of Group N semiconductor nanoparticle materials may be created by varying the attributes of composition, size, shape, and crystallinity of Group N semiconductor nanoparticles. Exemplary types of Group N semiconductor nanoparticle materials are yielded by variations including, but not limited by: 1.) single or mixed elemental composition; including alloys, core/shell structures, doped nanoparticles, and combinations thereof 2.) single or mixed shapes and sizes, and combinations thereof, and 3.) single form of crystallinity or a range or mixture of crystallinity, and combinations thereof.

The Group IV semiconductor nanoparticles may be made according to any suitable method, several of which are known, provided they are initially formed in an environment that is substantially inert, and substantially oxygen-free. As used herein, “inert” is not limited to only substantially oxygen-free. It is recognized that other fluids (i.e. gases, solvents, and solutions) may react in such a way that they negatively affect the electrical and photoconductive properties of Group IV semiconductor nanoparticles. Additionally, the terms “substantially oxygen-free” in reference to environments, solvents, or solutions refer to environments, solvents, or solutions wherein the oxygen content has been substantially reduced to produce Group IV semiconductor thin films having no more than 10¹⁷ to 10¹⁹ oxygen per cubic centimeter of Group IV semiconductor thin film.

One suitable way for making Group IV semiconductor nanoparticles of suitable quality in an inert, substantially oxygen-free environment includes plasma phase methods. For example, one plasma phase method, in which the particles are formed in an inert, substantially oxygen-free environment, is disclosed in U.S. patent application Ser. No. 11/155,340, filed Jun. 17, 2005; the entirety of which is incorporated herein by reference. Another example of a method for forming in Group IV semiconductor nanoparticles of suitable quality in an inert, substantially oxygen-free environment is laser pyrolysis.

It is contemplated that embodiments of doped Group IV semiconductor nanoparticles can be utilized to fabricate doped Group IV semiconductor thin film devices. In that regard, during plasma phase preparation, dopants can be introduced in to gas phase using either the plasma or laser pyrolysis methods for making Group IV semiconductor nanoparticles. For example, during the formation and growth of Group IV semiconductor nanoparticles, n-type Group IV semiconductor nanoparticles may be prepared using a plasma phase method in the presence of well-known gases such as phosphorous oxychloride, phosphine, or arsine. Alternatively, p-type semiconductor nanoparticles may be prepared during the formation and growth of Group IV semiconductor nanoparticles in the presence of boron difluoride, trimethyl borane, or diborane. For core/shell Group IV semiconductor nanoparticles, the dopant may be in the core or the shell or both the core and the shell.

After the preparation of quality Group IV semiconductor nanoparticles in an inert, substantially oxygen-free environment, the particles are formulated as dispersions or inks in an inert, substantially oxygen-free environment, so that they can be deposited on a solid support. In terms of preparation of the dispersions, the use of particle dispersal methods such as sonication, high shear mixers, and high pressure/high shear homogenizers are contemplated for use to facilitate dispersion of the particles in a selected solvent or mixture of solvents. A wide range of solvents and solutions are contemplated; taken across classes of solvents having a range of polarities. In that regard, solvents taken from classes such as aromatic and aliphatic hydrocarbon, alcohol, ketone, aldehyde, and ether, as well as silanes, and mixtures thereof. For example, inert dispersion solvents contemplated for use include, but are not limited to chloroform, tetrachloroethane, chlorobenzene, xylenes, mesitylene, diethylbenzene, 1,3,5 triethylbenzene (1,3,5 TEB), silanes, such as, but not limited by, tris(trimethylsilyl)silane (TTMSS), trimethylmethoxysilane (TMOS), triethylsilane (TES), ethanol, t-butanol, and solvent combinations thereof.

Various embodiments of Group IV semiconductor nanoparticle inks can be formulated by the selective blending of different types of Group IV semiconductor nanoparticles, or different types of Group IV semiconductor nanoparticles with other types of nanoparticles. Such selective blending yields control over the properties that a deposited porous compact, and therefore a fabricated Group IV semiconductor thin film will have.

For example, varying the packing density of Group IV semiconductor nanoparticles in a deposited thin layer is desirable for forming a variety of embodiments of Group IV photoconductive thin films. In that regard, Group IV semiconductor nanoparticle inks can be prepared in which various sizes of monodispersed Group N semiconductor nanoparticles are specifically blended to a controlled level of polydispersity for a targeted nanoparticle packing. Further, Group IV semiconductor nanoparticle inks can be prepared in which various sizes, as well as shapes are blended in a controlled fashion to control the packing density.

Still another example of what may achieved through the selective formulation of Group IV semiconductor nanoparticle inks by blending doped and undoped Group IV semiconductor nanoparticles. For example, various embodiments of Group IV semiconductor nanoparticle inks can be prepared in which the dopant level for a specific thin layer of a targeted device design is formulated by blending doped and undoped Group IV semiconductor nanoparticles to achieve the requirements for that layer. In still another example are embodiments of Group IV semiconductor nanoparticle inks that may compensate for defects in embodiments of Group IV photoconductive thin films. For example, it is known that in an intrinsic silicon thin film, oxygen may act to create undesirable energy levels. To compensate for this, low levels of p-type dopants, such as boron difluoride, trimethyl borane, or diborane, may be used to compensate for the presence of low levels of oxygen. By using Group IV semiconductor nanoparticles to formulate embodiments of inks, such low levels of p-type dopants may be readily introduced in embodiments of blends of the appropriate amount of p-doped Group IV semiconductor nanoparticles with various types of undoped Group IV semiconductor nanoparticles.

As will be discussed in more detail subsequently, embodiments of Group IV semiconductor promoter layers may be formed from porous compacts deposited using inks formulated by blending Group IV semiconductor nanoparticles and selected metal nanoparticles. For example, silicon nanoparticles may be mixed with a specified proportion of nickel nanoparticles or aluminum nanoparticles to achieve a controlled proportion of silicon to metal in an ink formulation. Such control may provide adequate levels of metal for seeding in a thin film fabricated from such inks, without the disadvantage of excess quantities of metal.

Other embodiments of Group IV semiconductor nanoparticle inks can be formulated that adjust the band gap of embodiments of Group N photoconductive thin films. For example, the band gap of silicon is about 1.1 eV, while the band gap of germanium is about 0.7 eV, and for alpha-tin is about 0.05 eV. Therefore, formulations of Group IV semiconductor nanoparticle inks may be selectively formulated so that embodiments of Group IV photoconductive thin films may have photon adsorption across a wider range of the electromagnetic spectrum.

Still other embodiments of inks can be formulated from alloys and core/shell Group IV semiconductor nanoparticles. For example, it is contemplated that silicon carbide semiconductor nanoparticles are useful for in the formation of a variety of semiconductor thin films and semiconductor devices. In other embodiments, alloys of silicon and germanium are contemplated. Such alloys may be made as discrete alloy nanoparticles, or may be made as core/shell nanoparticles.

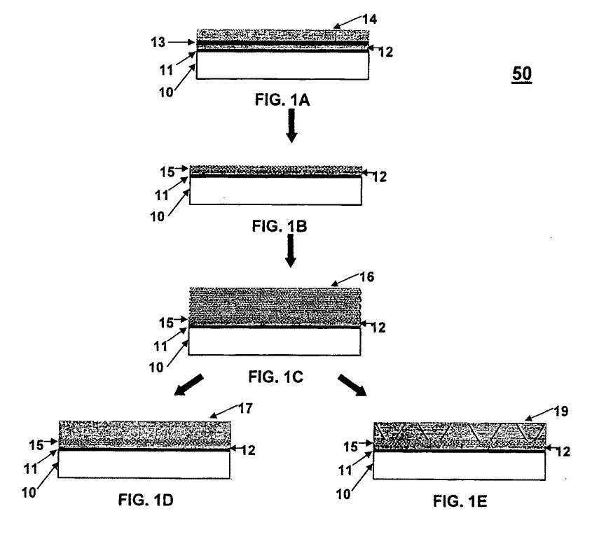

Fabrication process 50, shown in FIGS. 1A-1E, depicts the formation of a promoter layer (FIGS. 1A and 1B) for the fabrication of embodiments of Group IV semiconductor sintered thin films (FIG. 10) or embodiments of Group IV semiconductor polycrystalline thin films (FIG. 1E) from a deposited porous compact (FIG. 1A). The thin film structures of FIGS. 1A-1E are formed on substrate 10, upon which electrode, 12, and optionally an insulating or barrier layer 11 between the substrate 10 and electrode 12 may be disposed. Optionally, as will be discussed in more detail subsequently, metal layer 13 may be deposited upon first electrode 12.

For some embodiments of the thin film structures FIGS. 1A-1E, substrate materials may be selected from silicon dioxide-based substrates. Such silicon dioxide-based substrates include, but are not limited by, quartz, and glasses, such as soda lime and borosilicate glasses. For other embodiments of thin film structures FIGS. 1A-1E, flexible stainless steel sheet is the substrate of choice, while for still other embodiments of thin film structures FIGS. 1A-1E, the substrate may be selected from heat-durable polymers, such as polyimides and aromatic fluorene-containing polyarylates, which are examples of polymers having glass transition temperatures above about 300° C. The first electrode 12 is selected from conductive materials, such as, for example, but not limited by, aluminum, molybdenum, chromium, titanium, nickel, and platinum. For various embodiments of photoconductive devices contemplated, electrode 12 is between about 10 nm to about 1000 nm in thickness.

Optionally, an insulating layer 11 may be deposited on the substrate 10 before electrode 12 is deposited. Such an optional layer is useful when the substrate is a dielectric substrate, since it protects the subsequently fabricated Group IV semiconductor thin films from contaminants that may diffuse from the substrate into the Group IV semiconductor thin film during fabrication. When using a conductive substrate, the insulating layer 11 not only protects Group IV semiconductor thin films from contaminants that may diffuse from the substrate, but is required to prevent shorting. Additionally, an insulating layer 11 may be used to planarize an uneven surface of a substrate. The insulating layer 11 is selected from dielectric materials such as, for example, but not limited by, silicon nitride and alumina. For various embodiments of photoconductive devices contemplated the insulating layer 11 is about 5 nm to about 100 nm in thickness. In addition to the examples of metals listed for the electrode layer, examples of metal suitable for the optional metal layer 13 include, but are not limited by aluminum, molybdenum, titanium, nickel, platinum gold, iridium, iron, cobalt, ruthenium, rhodium, palladium, and osmium.

In FIG. 1A, using an embodiment of a Group IV semiconductor ink, a first porous compact 14 is deposited on first electrode 12 on substrate 10, and after processing, becomes promoter layer 15. It is contemplated that a variety of embodiments of promoter layer 15 of FIG. 1B may be fabricated using a variety of Group IV nanoparticle inks in conjunction with incorporation of a metal species. The metal species may be incorporated in the ink, or deposited either prior to the deposition of first nanoparticle layer 14, such as by optional metal layer 13, or after the deposition of first nanoparticle layer 14. Optionally, barrier layer 11 may be deposited between substrate 10 and first electrode 12.

In one embodiment, optional metal layer 13 may be deposited on first electrode layer 12. As previously discussed, electrode 12 may be selected from conductive materials, for example, metals such as, aluminum, molybdenum, chromium, titanium, nickel, and platinum, while optional metal layer 13 may be selected from, for example, metals such as, aluminum, molybdenum, titanium, nickel, platinum gold, iridium, iron, cobalt, ruthenium, rhodium, palladium, and osmium. As such, it is evident that there may be overlap of materials suitable for electrode layer 12 and optional metal layer 13. In that regard, in some embodiments of the fabrication of a promoter layer 15 of FIG. 1B, electrode layer 12 of between about 10 nm to about 1000 nm in thickness, may be deposited to serve the combined function of electrode layer 12 and optional metal layer 13. For example, molybdenum layer of about 200 nm to about 300 nm may be deposited on substrate 10, or for embodiments using a barrier layer, on optional barrier layer 11. In other embodiments of the fabrication of a promoter layer 15 of FIG. 1B, an optional metal layer 13 is deposited on electrode layer 12.

For example, on a molybdenum electrode layer 12 of about 125 nm to 200 nm in thickness, an optional metal layer 13 of about 10 nm to 100 nm may be deposited, using metals such as for example but not limited by, titanium, nickel, platinum gold, iridium, iron, cobalt, ruthenium, rhodium, palladium, and osmium. In either example of embodiments of electrode layer 12 and an optional metal layer 13; where the metals are either the same material or different, a first porous compact layer 14 of Group IV semiconductor nanoparticles is deposited. The thickness of the Group IV semiconductor first porous compact thin film may be about 100 nm to about 500 nm. As will be discussed in more detail subsequently, the porous compact on the metal layer is processed to form a promoter layer 15. In still other embodiments, a metal species may be incorporated into the porous compact layer 14 after the porous compact has been deposited onto electrode layer 12, using deposition methods, for example, such as ion implantation, sputtering, and chemical vapor deposition. Solutions of metal salts at targeted concentrations of the metal ion species may be applied to a porous compact, 16 and then distributed throughout said film, using for example, spin casting. Finally, as previously discussed, it is contemplated that embodiments of formulations of inks containing blends of Group IV semiconductor nanoparticles and may be useful for the formation of promoter layer 15 from porous compact 14 deposited directly on electrode layer 12, thus obviating the need for optional metal layer 13.

Regarding embodiments of promoter layer 15 formed on a substrate 10, the substrate material may be glass, upon which a barrier layer 11, such as alumina, has been deposited, and then an electrode layer 12, for example, such as a molybdenum electrode layer of between about 100 nm to about 150 nm is disposed on the barrier layer. In some embodiments, a metal layer 13 of between about 10 nm to about 100 nm is formed upon the electrode layer 12 using a metal such as, but not limited by titanium, nickel, platinum gold, iridium, iron, cobalt, ruthenium, rhodium, palladium, and osmium. For example, using a formulation of a Group IV semiconductor ink having Group IV semiconductor nanoparticles, such as silicon, germanium, or alloys thereof, of between about 2 nm to about 8 nm in diameter, a first porous compact 14 of between about 50 nm to about 200 nm is deposited on a titanium metal layer 13 of between about 10 nm to about 100 nm. In another embodiment of promoter layer 15, an ink formulation may contain nanoparticles such as silicon, germanium, or alloys thereof, of between about 1 nm to about 15 nm in diameter mixed with metal nanoparticles of between about 1 nm to 15 nm in diameter formed from a metal such as, but not limited by titanium, nickel, platinum gold, iridium, iron, cobalt, ruthenium, rhodium, palladium, and osmium. For example, an ink formulation of Group IV semiconductor nanoparticles and metal nanoparticles may be prepared from silicon, germanium, or alloys thereof, of between about 1 nm to about 15 nm in diameter mixed with nickel nanoparticles of 1 nm to 15 in diameter in a proportion of between about 100:1 (Group IV semiconductor:Ni) to about 10,000:1(Group IV semiconductor:Ni). A first porous compact 14 of between about 50 nm to about 200 nm is deposited on the electrode layer 12. In either example, a Group IV-metal semiconductor nanoparticle promoter layer 15 may be fabricated by heating the sample at between about 500° C. to about 550° C. for between about 1 minute to about 60 minutes.

In still other embodiments of enhancing the transition of Group IV semiconductor porous compact to Group IV semiconductor thin film, it is contemplated to use aluminum as the metal to promote the transition from a porous compact collection of Group IV semiconductor nanoparticles to a densified thin film. In one embodiment utilizing aluminum, an aluminum layer 13 may be deposited in a thickness of 10 nm to 100 nm on top of the molybdenum electrode 12. Using a formulation of a Group IV semiconductor nanoparticle ink, a porous compact is then deposited on the aluminum metal layer. In some embodiments, a formulation of an ink having a dispersion of Group IV semiconductor nanoparticles, for example, such as silicon, germanium, or alloys thereof, of between about 2 nm to about 10 nm diameter, is used to deposit a first porous compact 14 of between about 30 nm to about 200 nm on the aluminum layer. In other embodiments of using aluminum to induce the change from a Group IV semiconductor porous compact to a densified Group IV semiconductor thin film, an ink formulation may be prepared containing nanoparticles for example, of silicon, germanium, or alloys thereof, of between about 1 nm to about 15 nm in diameter mixed with aluminum nanoparticles of between about 1 nm to 15 nm in diameter in a proportion of between about 1:1 (Group IV semiconductor:Al) to about 10:1 (Group IV semiconductor:Al). In this process, having an excess of aluminum is not critical, as will be explained subsequently. A first porous compact 14 of between about 30 nm to about 200 nm is deposited on the electrode layer 12.

Regarding fabrication of a densified Group IV semiconductor thin film using aluminum to promote the densification process, during the fabrication process for producing a Group IV semiconductor thin film, an aluminum-induced phase change occurs. This results in the formation of a large grained polycrystalline layer, such as layer 19 of FIG. 1E. Such a large grained polycrystalline Group IV semiconductor layer will be inherently doped with aluminum to generally about not more than 10¹⁹ atoms/cc. In addition, on top of the large grain polycrystalline layer there is an aluminum metal layer which has separated in the fabrication process, and can be readily removed using standard processes for etching metals. In either example given, either depositing a Group IV semiconductor nanoparticle material on an aluminum layer, or using an ink formulation of Group N semiconductor nanoparticles with aluminum nanoparticles, an aluminum induced Group IV semiconductor densified thin film 19 may be fabricated by heating the Group IV semiconductor porous compact to between about 350° C. to about 580° C. for between about 5 minutes to about 3 hours.

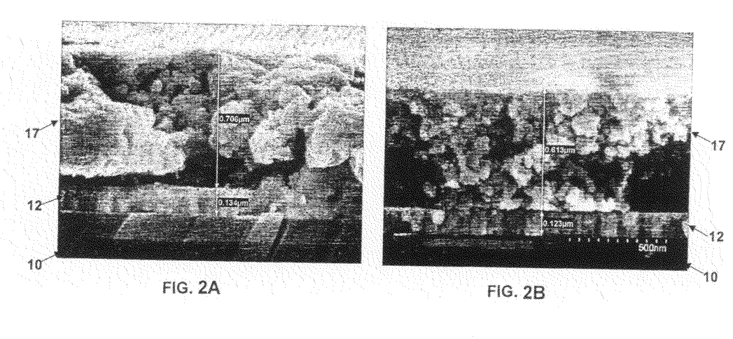

FIG. 2A and FIG. 2B demonstrate the effect of the use of an optional metal layer 13 on the grain size of a sintered thin film 17. In FIG. 2A, a sintered thin film 17 was fabricated on a 1″×1″×0.04″ quartz substrate, having a 100 nm molybdenum electrode layer 12 on which was deposited a 20 nm layer titanium optional metal layer 13 (not shown in the final fabricated film). A formulation of an ink was prepared as a 20 mg/ml solution of 8.5 nm nanocrystalline in a solution of chloroform/chlorobenzene (4:1) and sonicated in a water bath for 30 minutes. An aliquot of ink was deposited on the substrate in a volume sufficient to cover the substrate surface, and then a porous compact was formed by the spin cast process for one minute at 500 rpm. The porous compact was then subjected to a conditioning step of 100° C. for 30 minutes in vacuo at about 10 mTorr. A thermal ramp of between about 2° C./sec to about 3° C./sec was applied to the fabrication chamber to a final setting of 765° C. and was held at 765° C. for 15 minutes. Thin film 17 of FIG. 2B in an identical fashion as that described for thin film 17 of FIG. 2A, except the substrate for thin film 17 of FIG. 2B did not have the titanium metal layer deposited on the molybdenum layer. As can be seen in the comparison of the two embodiments of sintered thin film 17, the embodiment sintered thin film 17 of FIG. 2A has larger grain size that the sintered thin film 17 of FIG. 2B.

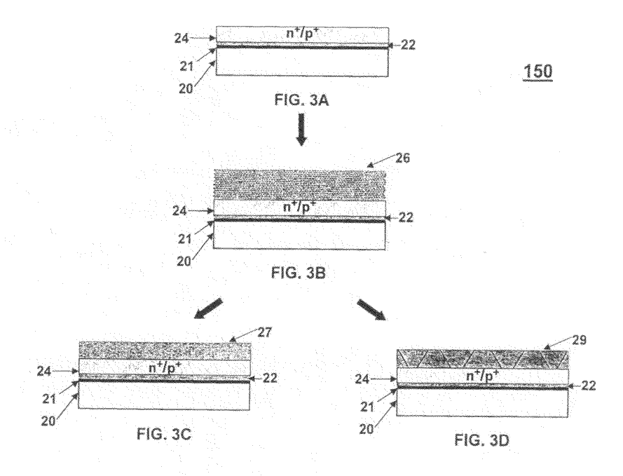

In FIGS. 3A-3D, the schematic of fabrication process 150 of a thin film using Group IV semiconductor nanoparticles on heavily doped Group IV semiconductor promoter layers is depicted. The thin film structures of FIGS. 3A-3D are formed on substrate 20, upon which an electrode 22, and optionally an insulating or barrier layer 21 between the substrate 20 and electrode 22 may be disposed. The considerations for substrate 20, electrode 22, and optionally insulating or barrier layer 21 for fabrication process 15 have been previously described for fabrication process 50. In FIG. 3A a highly doped Group IV semiconductor thin film layer 24 is disposed on the electrode layer 22. It is contemplated that highly doped Group IV semiconductor thin film layer 24 can be formed in a number of ways. For example, in some embodiments, highly doped Group IV semiconductor thin film layer 24 may be a polycrystalline thin film layer formed from a porous compact thin layer deposited on electrode layer 22 using an ink formulation of highly doped Group IV semiconductor nanoparticles. In other embodiments, highly doped Group IV semiconductor layer 24 may be a polycrystalline thin film layer deposited using conventional CVD processes. As indicated in FIG. 3A highly doped Group IV semiconductor layer 24 may be either n-doped with dopants such as phosphorous or arsenic or p-doped with dopants such as boron or aluminum. For highly doped films, the dopant levels may vary and are, for example, between about 10¹⁹ cm⁻³ to about 10²¹ cm⁻³. The highly doped Group IV semiconductor thin film layer 24 is between about 50 nm to about 200 nm in thickness. In FIG. 3B, porous compact 26 is deposited on highly doped Group IV semiconductor thin film layer 24 using a formulation of Group IV nanoparticle ink. After processing, either embodiments of Group IV semiconductor sintered thin films 27 (FIG. 3C) or embodiments of polycrystalline thin films 29 (FIG. 3D) are formed from porous compact 26.

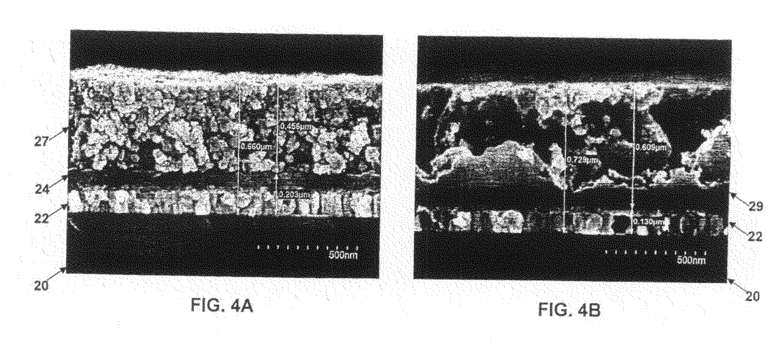

In FIG. 4A and FIG. 4B, the use of a highly doped n-type (N+) Group IV semiconductor thin film layer in the fabrication of embodiments of sintered and polycrystalline thin films from Group IV semiconductor nanoparticles is shown.

In FIG. 4A, a sintered thin film 27 was fabricated on a 1″×1″×0.04″ quartz substrate, having a 100 nm molybdenum electrode layer 22, on which was disposed an N+ polycrystalline silicon thin film 24 of about 100 nm formed using a CVD process, which was phosphorous-doped to a level of about 10²⁰ cm⁻³. A formulation of an ink was prepared as a 20 mg/ml solution of 8.5 nm nanocrystalline in a solution of chloroform/chlorobenzene (4:1) and sonicated in a water bath for 30 minutes. An aliquot of ink was deposited on the substrate in a volume sufficient to cover the substrate surface, and then a porous compact was formed by the spin cast process for one minute at 500 rpm. The porous compact was then subjected to a conditioning step of 100° C. for 30 minutes in vacuo at about 10 mTorr. A thermal ramp of between about 2° C./sec to about 3° C./sec was applied to the fabrication chamber to a final setting of 750° C. and was held at 750° C. for 15 minutes.

In FIG. 4B, a polycrystalline thin film 29 was fabricated on a 1″×1″×0.04″ quartz substrate, having a 100 nm molybdenum electrode layer 22, on which was disposed an N+ polycrystalline silicon thin film 24 of about 100 nm formed using a CVD process, which was phosphorous-doped to a level of about 10²⁰ cm⁻³. The process steps as described for the sintered thin film 27 were followed for the fabrication of polycrystalline thin film 29, except that the final temperature of the fabrication chamber was 800° C., which was held for 15 minutes after the ramp of between about 2° C./sec to about 3° C./sec to the target temperature. The N+ polycrystalline silicon thin film 24 is not apparent in FIG. 4B, since it was an effective promoter layer for the formation of polycrystalline thin film 29. In addition to the visible fusion of the silicon nanoparticle grains to the polycrystalline silicon in FIG. 4B, it is clear in comparing FIG. 4B to FIG. 4A that the grain sizes in the thin film of FIG. 4B are bigger than that of FIG. 4A.

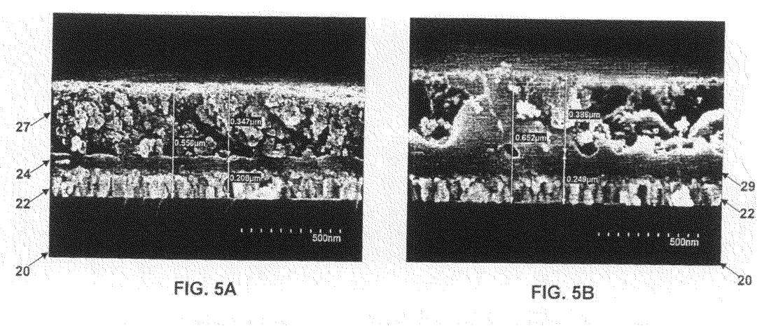

Similarly, FIG. 5A and FIG. 5B, the use of a highly doped p-type (P+) Group IV semiconductor thin film layer in the fabrication of embodiments of sintered and polycrystalline thin films from Group IV semiconductor nanoparticles is shown.

In FIG. 5A, a sintered thin film 27 was fabricated on a 1″×1″×0.04″ quartz substrate, having a 100 nm molybdenum electrode layer 22, on which was disposed an P+ polycrystalline silicon thin film 24 of about 100 nm formed using a CVD process, which was boron-doped to a level of about 10²⁰ cm⁻³. A formulation of an ink was prepared as a 20 mg/ml solution of 8.5 nm nanocrystalline in a solution of chloroform/chlorobenzene (4:1) and sonicated in a water bath for 30 minutes. An aliquot of ink was deposited on the substrate in a volume sufficient to cover the substrate surface, and then a porous compact was formed by the spin cast process for one minute at 500 rpm. The porous compact was then subjected to a conditioning step of 100° C. for 30 minutes in vacuo at about 10 mTorr. A thermal ramp of between about 2° C./sec to about 3° C./sec was applied to the fabrication chamber to a final setting of 750° C. and was held at 750° C. for 15 minutes.

In FIG. 5B, a polycrystalline thin film 29 was fabricated on a 1″×1″×0.04″ quartz substrate, having a 100 nm molybdenum electrode layer 22, on which was disposed an P+ polycrystalline silicon thin film 24 of about 100 nm formed using a CVD process, which was boron-doped to a level of about 10²⁰ cm⁻³. The process steps as described for the sintered thin film 27 were followed for the fabrication of polycrystalline thin film 29, except that the final temperature of the fabrication chamber was 800° C., which was held for 15 minutes after the ramp of between about 2° C./sec to about 3° C./sec to the target temperature. The P+ polycrystalline silicon thin film 24 is not apparent in FIG. 5B, since it was an effective promoter layer for the formation of polycrystalline thin film 29. In addition to the visible fusion of the silicon nanoparticle grains to the polycrystalline silicon in FIG. 5B, it is clear in comparing FIG. 5B to FIG. 5A that the grain sizes in the thin film of FIG. 5B are bigger than that of FIG. 5A.

While principles of the disclosed preparation of substrates for the enhancement of thin film fabrication using Group IV semiconductor nanoparticles have been described in connection with specific embodiments, it should be understood clearly that these descriptions are made only by way of example and are not intended to limit the scope of what is disclosed. In that regard, what has been disclosed herein has been provided for the purposes of illustration and description. It is not intended to be exhaustive or to limit what is disclosed to the precise forms described. Many modifications and variations will be apparent to the practitioner skilled in the art. For example, though metal-Group IV semiconductor promoter layers, and heavily doped promoter layers were given a two examples, one of ordinary skill in the art would recognize that combinations of metals and dopants produce still other embodiments of promoter layers. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

What is claimed is:

1. A method for producing a thin film promoter layer, comprising:
depositing a Group IV semiconductor ink on a substrate, the Group IV semiconductor ink including a set of Group IV semiconductor nanoparticles and a set of metal nanoparticles to form a porous compact;
heating the substrate to a first temperature between about 350° C. to about 765° C. and for a first time period between 5 min to about 3 hours.

2. The method of claim 1, wherein the set of Group IV semiconductor nanoparticles includes at least one of Si, Ge, SiGe, and SiC.

3. The method of claim 1, wherein each Group N semiconductor nanoparticle of the set of Group IV semiconductor nanoparticles is between 1 and 15 nm in diameter.

4. The method of claim 1, wherein each metal nanoparticle of the set of metal nanoparticles is between 1 and 15 nm in diameter.

5. The method of claim 1, wherein the set of metal nanoparticles includes at least one of aluminum, titanium, nickel, molybdenum, and cobalt.

6. The method of claim 1 further including the step of disposing a barrier layer on the substrate, before the step of depositing a Group N semiconductor ink on a substrate.

7. The method of claim 1, wherein the proportion of the set of Group IV semiconductor nanoparticles to the set of metal nanoparticles is between 1:1 to about 10:1.

8. The method of claim 1, wherein the step of heating the substrate to a first temperature between about 350 C to about 580 C and for a first time period between 5 min to about 3 hours further includes forming a top aluminum layer.

9. The method of claim 8, further including the step of removing the top aluminum layer using a standard metal etching process, after the step of heating the substrate to a first temperature.

10. The method of claim 1, further including the step of conditioning the porous compact in vacuo at a second temperature of about 100° C. and for a second time period of about 30 minutes, before the step of heating the substrate to a first temperature.

11. A method for producing a thin film promoter layer, comprising:
depositing a Group IV semiconductor ink on a substrate, the substrate having an electrode layer disposed thereon, the Group IV semiconductor ink including a set of Group IV semiconductor nanoparticles form a porous compact;
heating the substrate to a first temperature between about 350° C. to about 580° C. and for a first time period between 5 min to about 3 hours.

12. The method of claim 11, wherein the set of Group IV semiconductor nanoparticles includes at least one of Si, Ge, SiGe, and SiC.

13. The method of claim 11, wherein each Group IV semiconductor nanoparticle of the set of Group IV semiconductor nanoparticles is between 1 and 15 nm in diameter.

14. The method of claim 11, wherein the electrode layer includes at one of aluminum, molybdenum, chromium, titanium, nickel, and platinum.

15. The method of claim 11, where the porous compact is between 100 nm and about 500 nm in thickness.

16. The method of claim 11 further including the step of disposing a barrier layer on the substrate, before the step of depositing a Group IV semiconductor ink on a substrate.

17. The method of claim 11, further including the step of forming a metal layer by one of ion implantation, sputtering, metal salt deposition, and chemical vapor deposition, after the step of heating the substrate to a first temperature.

18. The method of claim 17, where the metal layer is between about 10 nm and about 1000 nm.

19. The method of claim 18, wherein the metal layer includes a set of metal species.

20. The method of claim 19, during the step of heating the substrate to a first temperature, at least of portion of the metal species is incorporated into the porous compact.

21. The method of claim 11, further including the step of conditioning the porous compact in vacuo at a second temperature of about 100° C. and for a second time period of about 30 minutes.
